(19) United States
(12) Patent Application Publication
(10) Pub. No.: US 2025/0040082 A1
(43) Pub. Date: Jan. 30, 2025

(54) SEALING STRUCTURE FOR IMMERSION COOLING APPARATUS DEVICE

(71) Applicant: AIP Inc., New Taipei City (TW)

(72) Inventor: Lee Chia, New Taipei City (TW)

(73) Assignee: AIP Inc., New Taipei City (TW)

(21) Appl. No.: 18/733,868

(22) Filed: Jun. 5, 2024

Related U.S. Application Data
(63) Continuation-in-part of application No. 18/595,501, filed on Mar. 5, 2024.
Application No. 18/595,501 is a continuation-in-part of application No. 18/510,668, filed on Nov. 16, 2023.
Application No. 18/510,668 is a continuation of application No. 63/528,933, filed on Jul. 26, 2023.
(60) Provisional application No. 63/617,449, filed on Jan. 4, 2024.
(60) Provisional application No. 63/617,447, filed on Jan. 4, 2024.

(51) Int. Cl. H05K 7/20; F16J 15/06

(52) U.S. Cl. CPC H05K 7/20272; F16J 15/06; H05K 7/20236

(57) ABSTRACT

A sealing structure for an immersion cooling apparatus housing and cooling an optoelectronic processing device includes a first lid portion, a second lid portion detachably connected to the first lid portion, and a sealing component. The sealing component includes a first sealing part disposed on the first lid portion and a second sealing part disposed on the second lid portion. The first lid portion, the second lid portion, and the sealing component jointly define a sealing lid hermetically covering an opening portion of a tank body included in the immersion cooling apparatus. Part of optical fibers included in the optoelectronic processing device are sandwiched between and encompassed by the first sealing part and the second sealing part.

### CROSS REFERENCE TO RELATED APPLICATIONS

This application claims the benefit of U.S. provisional patent application Ser. No. 63/617,449, filed Jan. 4, 2024, the entirety of which is incorporated by reference herein.

This application is a continuation-in-part of U.S. patent application Ser. No. 18/595,501, filed Mar. 5, 2024, which claims the priority of U.S. provisional patent application Ser. No. 63/617,447, filed Jan. 4, 2024. The '501 application is a continuation-in-part of Ser. No. 18/510,668, filed Nov. 16, 2023, which claims the priority of U.S. provisional patent application Ser. No. 63/528,933, filed Jul. 26, 2023, the entireties of which are incorporated by reference herein.

### BACKGROUND OF INVENTION

### 1. Field of Invention

The present invention relates to a technical field of sealing, and particularly to a sealing structure for an immersion cooling apparatus, which houses and cools an optoelectronic processing device.

### 2. Related Art

Optoelectronic integrated circuits (OEICs), using photons instead of electrons for calculation and data transmission in integrated circuits, bring great benefits to the development of industries requiring high-performance data exchange, long-distance interconnection, 5G facilities, and computing equipment. OEICs are configured with photonic integrated circuits (PICs) and electronic integrated circuits (EICs) and are generally co-packaged as co-packaged optics (CPO). These days, CPO modules are extensively used in servers or devices dealing with high density data. As is known, servers generate a great deal of heat energy during operation. To avoid poor operational performance, circuit boards in the servers are immersed in heat dissipation liquid of cooling containers to absorb heat energy generated by electronic components. Such a heat exchange manner requires a large amount of heat dissipation liquid or fluid coolant that is susceptible to leakage from the cooling containers. In addition, even if the cooling containers can be sealed, it is difficult to take out or replace signal transmission lines extending in and out of the cooling containers to connect to the CPO modules. Unfortunately, there is no mature or effective solution for solving the problems.

### SUMMARY OF INVENTION

An object of the present application is to provide a sealing structure for an immersion cooling apparatus to ensure an optoelectronic processing device is housed in the immersion cooling apparatus in a hermetic state and is maintained in a desired temperature, thus enabling a good condition of the optoelectronic processing device.

Another object of the present application is to provide a sealing structure for an immersion cooling apparatus that can achieve ease of replacement of signal transmission lines while ensuring sealing of the immersion cooling apparatus.

To achieve the above-mentioned objects, one aspect of the present application is to provide a sealing structure for an immersion cooling apparatus, the immersion cooling apparatus housing and cooling an optoelectronic processing device including a processing unit and a plurality of optical fibers connected to the processing unit. The sealing structure includes a first lid portion, a second lid portion, and a sealing component. The second lid portion is detachably connected to the first lid portion. The sealing component includes a first sealing part and a second sealing part, the first sealing part disposed on the first lid portion and including a first sealing surface, the second sealing part disposed on the second lid portion and including a second sealing surface, and the first lid portion, the second lid portion, and the sealing component jointly defining a sealing lid hermetically covering an opening portion of a tank body included in the immersion cooling apparatus. The first sealing surface and the second sealing surface are in contact with each other, and part of each of the optical fibers is sandwiched between and encompassed by the first sealing surface and the second sealing surface.

Optionally, the first sealing part includes a first inner surface opposite to the first sealing surface and being attached to the first lid portion, and a first lower ring portion extending from the first inner surface toward the first lid portion and tightened against the first lid portion.

Optionally, the first sealing part further includes a first upper ring portion arranged on the first inner surface and located above and extending beyond the first lower ring portion.

Optionally, the second sealing part includes a second inner surface opposite to the second sealing surface and being attached to the second lid portion, and a second lower ring portion extending from the second inner surface toward the second lid portion and tightened against the second lid portion.

Optionally, the second sealing part further includes a second upper ring portion arranged on the second inner surface and located above and extending beyond the second lower ring portion.

Optionally, the first lid portion includes a first recessed portion arranged on a side of the first lid portion, and the second lid portion includes a second recessed portion arranged on a side of the second lid portion and facing the first recessed portion. A part of the first sealing part is positioned in the first recessed portion, and a part of the second sealing part is positioned in the second recessed portion.

Optionally, the first lid portion includes a first tab protruding outward from peripheries of the first lid portion, the second lid portion includes a second tab protruding outward from peripheries of the second lid portion, and the first tab and the second tab are positioned on the opening portion of the immersion cooling apparatus.

Optionally, the first lid portion includes a plurality of fastening elements positioned on opposite ends of the first lid portion, and the second lid portion includes a plurality of fixing portions positioned on opposite ends of the second lid portion and structured to connect to the fastening elements, respectively.

Optionally, the sealing structure further includes a connecting device positioned on an entrance opening formed in the tank body. The connecting device includes a connecting base on which a plurality of optical connector adapters and a plurality of interconnectors are arranged.

Optionally, the connecting device further includes a fixing board connected between the connecting base and the sealing lid, and a circuit board mounted on the fixing board.

Optionally, the immersion cooling apparatus includes a storage casing including a storage space, a rack, and a plurality of terminal connectors arranged on the rack, wherein the tank body is placed in and drawable from the storage space, and the optical connector adapters and the interconnectors are electrically connected to the terminal connectors, respectively.

Optionally, the optoelectronic processing device includes a main board, a load board disposed on the main board, and a co-packaged optics module disposed on the load board. The co-packaged optics module includes a first casing arranged on the load board, a second casing assembled with the first casing, an optoelectronic transceiver module, and the processing unit, and the optoelectronic transceiver module and the processing unit are sealed between the first casing and the second casing.

Optionally, the optoelectronic transceiver module includes a detachable optical coupling structure includes a first connector and a second connector detachably connected to the first connector.

Optionally, the optoelectronic processing device further includes a plurality of functional lines, a part of each of the functional lines extends into the co-packaged optics module, and another part of each of the functional lines passes through the first sealing part or is sandwiched between and encompassed by the first sealing surface and the second sealing surface.

Another aspect of the present application is to provide a sealing structure for an immersion cooling apparatus housing and cooling an optoelectronic processing device. The sealing structure includes a first lid portion, a second lid portion detachably connected to the first lid portion, and a sealing component disposed on the first lid portion and the second lid portion. The optoelectronic processing device includes a load board, a first casing arranged on the load board, a second casing assembled with the first casing, and an optoelectronic transceiver module sealed between the first casing and the second. The optoelectronic transceiver module includes a detachable optical coupling structure, and the optical coupling structure includes a first connector disposed on the load board. The first connector includes a base, and a waveguide device disposed in the base. A second connector includes an optical fiber assembly and is detachably connected to the first connector.

Optionally, the sealing component includes a first sealing part and a second sealing part, the first sealing part disposed on the first lid portion and including a first sealing surface, the second sealing part disposed on the second lid portion and including a second sealing surface, and the first lid portion, the second lid portion, and the sealing component jointly defining a sealing lid hermetically covering an opening portion included in the immersion cooling apparatus. The first sealing surface and the second sealing surface are in contact with each other, and part of each of the optical fibers are sandwiched between and encompassed by the first sealing surface and the second sealing surface.

In the embodiments of the present application, the sealing structure provided in the embodiments of the present application renders the optoelectronic processing device in the tank body of the immersion cooling apparatus excellent hermetic, which prevents the fluid coolant leakage from the tank body, thus ensuring the co-packaged optics module is maintained in a desired temperature and enabling a good condition of the optoelectronic processing device. In addition, the detachable combination of the first lid portion and the second lid portion along with the first sealing part and the second sealing part obtains the advantage of easy replacement of the optical fiber assembly, thereby solving the problem of difficulty in replacing signal transmission lines.

### BRIEF DESCRIPTION OF DRAWINGS

To describe the technical solutions in the embodiments of the present application, the following briefly introduces the drawings for describing the embodiments. The drawings in the following description show merely some embodiments of the present application, and a person skilled in the art may still derive other drawings from these drawings without creative efforts.

FIG. 1 is a schematic assembly view of a sealing structure for an immersion cooling apparatus in accordance with an embodiment of the present application.

FIG. 2 is a schematic exploded view of the sealing structure of FIG. 1.

FIG. 2A is a schematic enlarged cross-sectional view of part of the sealing structure shown in FIG. 1.

FIG. 2B is a schematic perspective view of a sealing component in accordance with an embodiment of the present application.

FIG. 3 is a schematic front side view of FIG. 1.

FIG. 4 is another assembly view of the sealing structure of FIG. 1.

FIG. 5 is a schematic perspective exploded view of an optoelectronic processing device in accordance with an embodiment of the present application.

FIG. 5A is a schematic assembly view of an optoelectronic transceiver module of the optoelectronic processing device in accordance with an embodiment of the present application.

FIG. 5B is a schematic exploded view of FIG. 5A.

FIG. 6 is a schematic partial cross-sectional view of a tank body of the immersion cooling apparatus in accordance with an embodiment of the present application.

FIG. 7 is a schematic perspective view showing the sealing structure is pluggable into the tank body in accordance with an embodiment of the present application.

FIG. 8 schematically shows a partial cross-sectional view of the tank body of FIG. 7.

FIG. 9 is an enlarged cross-sectional view schematically showing a sealing structure is plugged into an immersion cooling apparatus in accordance with an embodiment of the present application.

FIG. 10 is a schematic perspective view showing a tank body with a sealing structure is placed in a storage casing in accordance with an embodiment of the present application.

FIG. 11 is a schematic perspective view showing the tank body of FIG. 10 is drawn from the storage casing.

### DESCRIPTION OF PREFERRED EMBODIMENTS

The following embodiments are referring to the appendix drawings for exemplifying specific implementable embodiments of the present application. Directional terms described by the present application, such as upper, lower, front, back, left, right, inner, outer, side, etc., are only directions by referring to the drawings, and thus the directional terms are used to describe and understand the present application, but the present application is not limited thereto.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present application. In addition, the present application may repeat reference numerals and/or letters in the various examples. This repetition is for the purpose of simplicity and clarity and does not in itself dictate a relationship between the various embodiments and/or configurations discussed.

The present invention provides a sealing structure for an immersion cooling apparatus. The immersion cooling apparatus is configured to house and cool an optoelectronic processing device, which is operable in the immersion cooling apparatus with a fluid coolant, and the sealing structure of the present application ensures the optoelectronic processing device is housed in the immersion cooling apparatus in a hermetic state and is maintained in a desired temperature, thus enabling a good condition of the optoelectronic processing device in use.

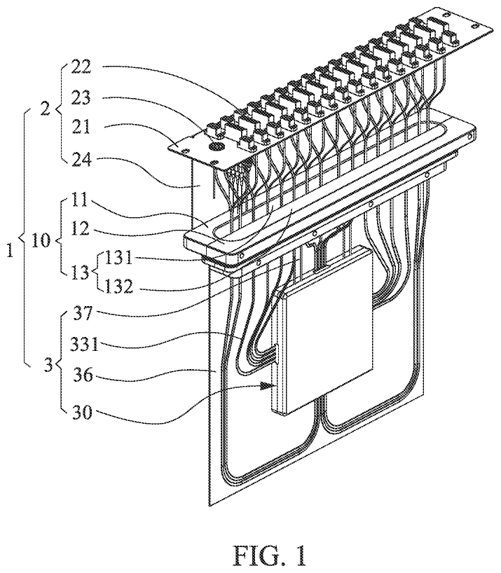

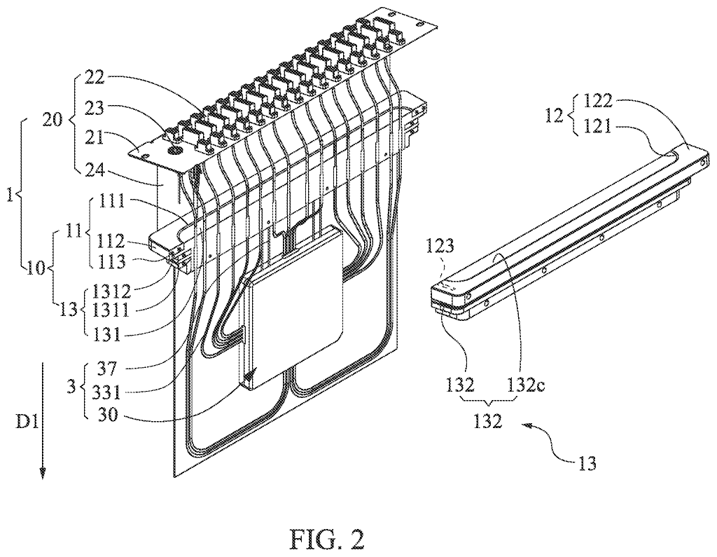

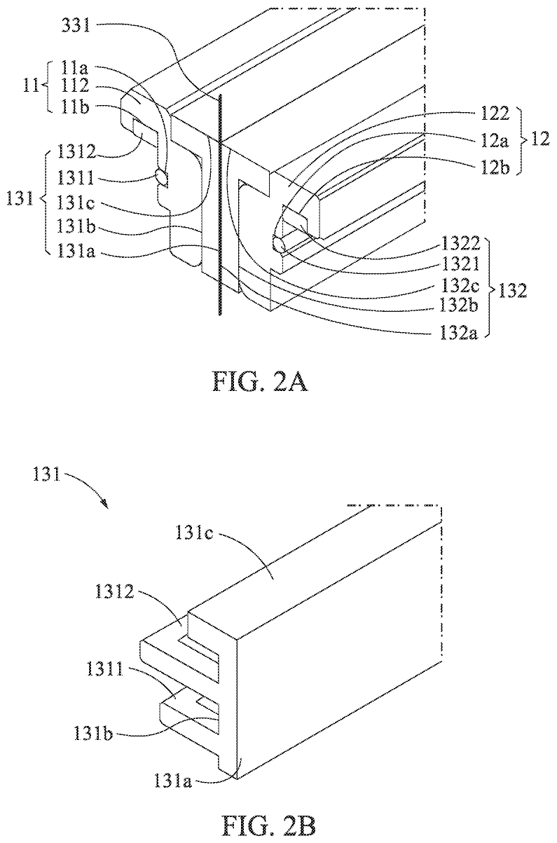

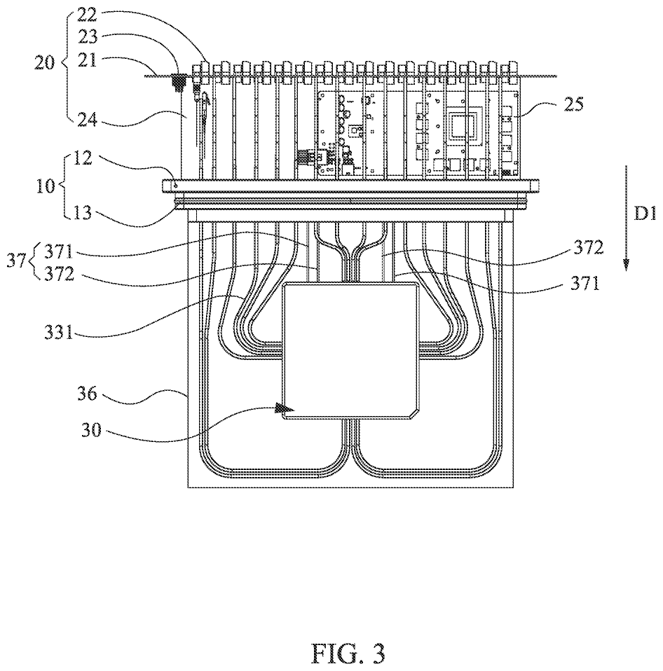

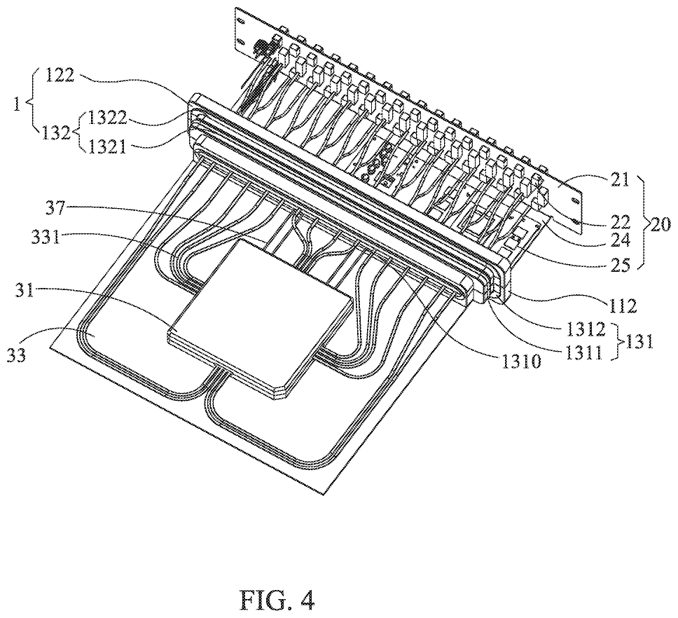

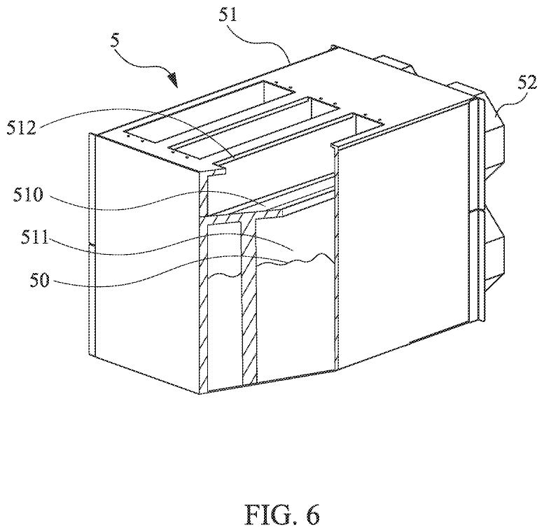

Referring to FIGS. 1 to 4, FIG. 1 is a schematic assembly view of a sealing structure 1 for an immersion cooling apparatus 5 (see FIG. 6 described below) in accordance with an embodiment of the present application, FIG. 2 is a schematic exploded view of the sealing structure 1 of FIG. 1, FIG. 2A is a schematic enlarged cross-sectional view of part of the sealing structure 1 shown in FIG. 1, FIG. 2B is a schematic perspective view of a sealing component 13, FIG. 3 is a schematic front side view of FIG. 1, and FIG. 4 is another assembly view of the sealing structure 1 of FIG. 1. As shown in FIGS. 1 and 2, the present application provides the sealing structure 1 for an immersion cooling apparatus 5 (see FIG. 6 described below) in which an optoelectronic processing device 3 is positioned. In some embodiments, the optoelectronic processing device 3 includes a co-packaged optics module 30, which is connected with a plurality of signal transmission lines including a plurality of optical fibers 331 and functional lines 37 for signal transmission with external devices.

Referring to FIGS. 1 and 2, the sealing structure 1 includes a first lid portion 11, a second lid portion 12 detachably connected to the first lid portion 11, and a sealing component 13. In some embodiments, the first lid portion 11 and the second lid portion 12 are symmetrically sized and shaped in such a way that they can be combined as a whole with the sealing component 13 to form a sealing lid 10. The sealing lid 10 is structured to hermetically cover an opening portion 510 of the immersion cooling apparatus 5 (see FIG. 6 described below). In some embodiments, the sealing component 13 can be made of a material including, such as rubber, silicon, fluoro-rubber (also known as Viton, FPM, or FKM), silicone, or silicone compound, but is not limited thereto. As shown in FIGS. 2 and 2A, the sealing component 13 includes a first sealing part 131 and a second sealing part 132 that are each provided as separate items. The first sealing part 131 is disposed on the first lid portion 11 and includes a first sealing surface 131a facing the second lid portion 12. The second sealing part 132 is disposed on the second lid portion 12 and includes a second sealing surface 132a facing the first sealing surface 131a. As shown in FIGS. 1 and 2A, after the first lid portion 11 and the second lid portion 12 are assembled, the first sealing surface 131a and the second sealing surface 132a are in contact with each other such that part of each of the optical fibers 331 is sandwiched between and encompassed by the first sealing surface 131a and the second sealing surface 132a.

Referring to FIGS. 1 to 3, the first lid portion 11 is bar-like shaped and has a stair-like edge profile to improve bonding strength between the first sealing part 131 and the first lid portion 11 and also enhance sealing performance at the opening portion 510 (see FIG. 6 described below). In some embodiments, the first lid portion 11 includes a first recessed portion 111 and a first tab 112. In detail, as shown in FIGS. 2 and 2A, the first recessed portion 111 is arranged on a length side of the first lid portion 11 and is recessed into the first lid portion 11. The first tab 112 is arranged on a top of the first lid portion 11 and protrudes outward from peripheries of the first lid portion 11. Similarly, the second lid portion 12 includes a second recessed portion 121 and a second tab 122. In detail, the second recessed portion 121 is arranged on a length side of the second lid portion 12 and is recessed into the second lid portion 12. The second tab 122 is arranged on a top of the second lid portion 12 and protrudes outward from peripheries of the second lid portion 12.

As shown in FIGS. 2, 2A, and 3, the first recessed portion 111 and the first tab 112 jointly form the stair-like edge profile in a depth direction D1 from an outermost top surface of the first lid portion 11 to an outermost bottom surface of the first lid portion 11, and the second recessed portion 121 and the second tab 122 jointly form the stair-like edge profile in the depth direction D1. In some embodiments, as shown in FIG. 2A, the first lid portion 11 further includes a first lower slot 11a and a first upper slot 11b. Specifically, the first lower slot 11a is formed on an outer surface of the first lid portion 11 and extends along an entire outer edge of the first lid portion 11. The first upper slot 11b is formed on a bottom surface of the first tab 112 and extends along an entire outer edge of the first tab 112. Preferably, an orthographic projection of the first upper slot 11b on a horizontal plane is not coincident with an orthographic projection of the first lower slot 11a on the horizontal plane.

Similarly, as shown in FIG. 2A, the second lid portion 12 further includes a second lower slot 12a and a second upper slot 12b. Specifically, the second lower slot 12a is formed on an outer surface of the second lid portion 12 and extends along an entire outer edge of the second lid portion 12. The second upper slot 12b is formed on a bottom surface of the second tab 122 and extends along an entire outer edge of the second tab 122. Preferably, an orthographic projection of the second upper slot 12b on the horizontal plane is not coincident with an orthographic projection of the second lower slot 12a on the horizontal plane.

Referring to FIGS. 2 to 4, the first sealing part 131 includes a first inner surface 131b, which is opposite to the first sealing surface 131a and is attached to the first lid portion 11. In detail, as shown in FIGS. 2A and 2B, a top of the first sealing part 131 bends toward the first recessed portion 111 to form a first bent portion 131c, which is positioned in the first recessed portion 111 in such a way that the first bent portion 131c completely fills up the first recessed portion 111. In this embodiment, as shown in FIGS. 2A and 2B, the first sealing part 131 further includes a first lower ring portion 1311 and a first upper ring portion 1312. In detail, the first lower ring portion 1311 integrally extends from the first inner surface 131b toward the first lid portion 11 and is tightened against the first lid portion 11 with a snug fit in the first lower slot 11a. The first upper ring portion 1312 integrally extends from the first inner surface 131b beyond the first lower ring portion 1311 and is located above the first lower ring portion 1311.

As shown in FIGS. 2, 2A, and 2B, similarly to the first sealing part 131, the second sealing part 132 includes a second inner surface 132b, which is opposite to the second sealing surface 132a and is attached to the second lid portion 12. In detail, a top of the second sealing part 132 bends toward the second recessed portion 121 to form a second bent portion 132c, which is positioned in the second recessed portion 121 in such a way that the second bent portion 132c completely fills up the second recessed portion 121. In this embodiment, the second sealing part 132 further includes a second lower ring portion 1321 and a second upper ring portion 1322. In detail, the second lower ring portion 1321 integrally extends from the second inner surface 132b toward the second lid portion 12 and is tightened against the second lid portion 12 with a snug fit in the second lower slot 12a. The second upper ring portion 1322 integrally extends from the second inner surface 132b beyond the second lower ring portion 1321 and is located above the second lower ring portion 1321.

As described above, the provision of the first recess portion 111 and the second recessed portion 121 increases the area in contact with the sealing component 13, thus further enhancing the bonding strength between the first sealing part 131 and the first lid portion 11 and between the second sealing part 132 and the second lid portion 12.

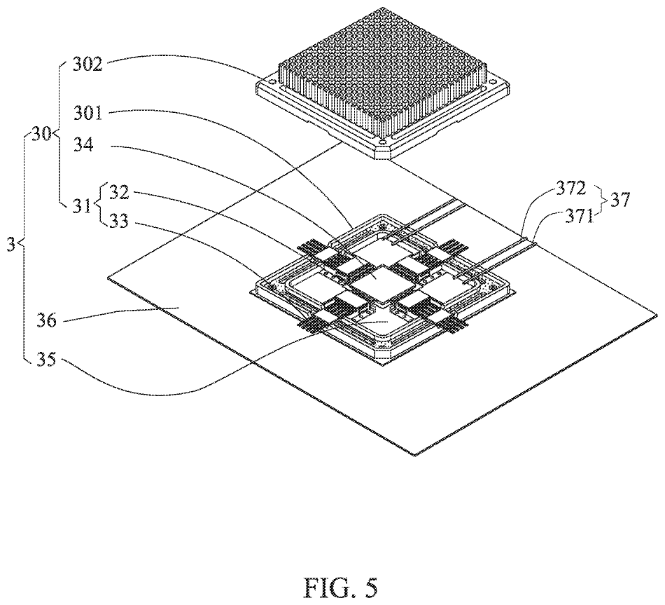

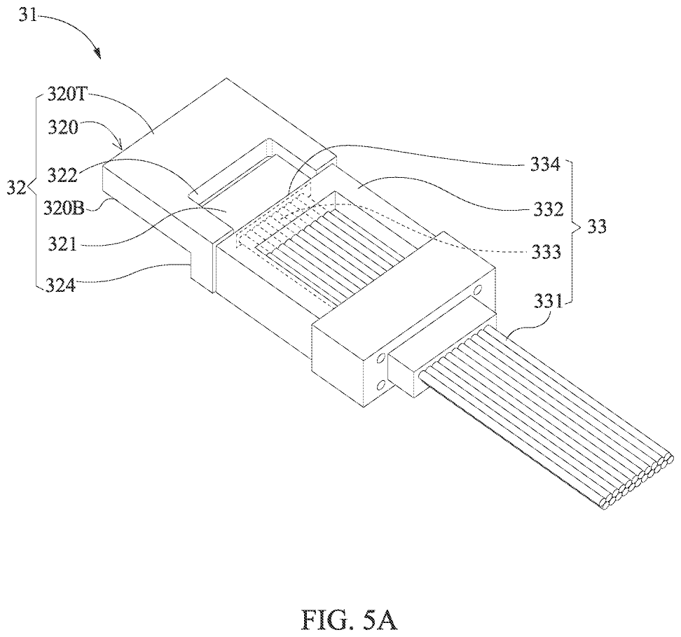

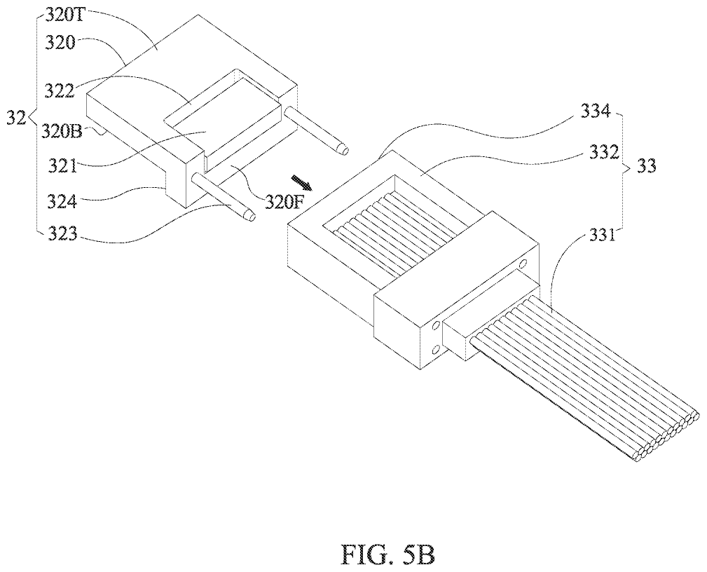

Referring to FIGS. 1 and 2, a plurality of fastening elements 113 are positioned on opposite ends of the first lid portion 11 facing the second lid portion 12, and a plurality of fixing portions 123 are positioned on opposite ends of the second lid portion 12 corresponding to the fastening elements 113. In some embodiments, as shown in FIG. 2, the fastening elements 113 are each pin-like in shape and are spaced apart from each other in the depth direction D1. The fixing portions 123 are each cylinder in shape such that the fastening elements 113 can be inserted into and in a snug fit engagement with the fixing portions 123, respectively. In some embodiments, the fastening elements 113 and the fixing portions 123 may also be firmly fixed through, e.g., structural coupling, screw fastening, or the like. By means of the combination of the first lid portion 11 and the second lid portion 12, the first sealing part 131 and the second sealing part 132 can be tightly attached to each other so that the part of each of the optical fibers 331 is sandwiched between and encompassed by the first sealing surface 131a and the second sealing surface 132a (see FIG. 2A). The detachable combination of the first lid portion 11 and the second lid portion 12 along with the first sealing part 131 and the second sealing part 132 can also obtain the advantage of easy replacement of the optical fiber assembly 33 (see FIG. 5 to FIG. 5B) in case of damage or malfunction.

As shown in FIG. 4, in this embodiment, a part of each of the functional lines 37 extends into the co-packaged optics module 30 and another part penetrates the first sealing part 131. In detail, a plurality of through holes 1310 are pre-formed in the first sealing part 131 to allow insertion of the functional lines 37. Alternatively, the functional lines 37 may penetrate the second sealing part 132 or both the first sealing part 131 and the second sealing part 132 according to actual requirements. In some other embodiments, part of the functional lines 37 may also be sandwiched between and encompassed by the first sealing surface 131a and the second sealing surface 132a. In some embodiments, as shown in FIG. 5, the functional lines 37 include two power lines 371 and two pressure-regulated pipes 372. The power lines 371 are used to provide power for the components disposed on the load board 35. The pressure-regulated pipes 372 are used to maintain the atmospheric pressure inside the co-packaged optics module 30 in response to temperature fluctuations in the co-packaged optics module 30 so as to ensure a normal operation of the co-packaged optics module 30.

Referring to FIGS. 1 and 3 to 4, the sealing structure 1 further includes a connecting device 20 to hold the optical fibers 331 and the functional lines 37 outside of the sealing lid 10. In some embodiments, the connecting device 20 includes a connecting base 21, a plurality of optical connector adapters 22, a plurality of interconnectors 23, a fixing board 24, and a circuit board 25. In detail, the optical connector adapters 22 and the interconnectors 23 are arranged on the connecting base 21 for the connection with external connectors or adapters. The fixing board 24 is connected between the connecting base 21 and the sealing lid 10 to hold the connecting base 21 above the sealing lid 10. The circuit board 25 is mounted on the fixing board 24 for disposition of data processing components. In some embodiments, the optical connector adapters 22 and the interconnectors 23 are connected to the optical fibers 331 and the functional lines 37 and are used to transmit signals or power for the co-packaged optics module 30, but types of the optical connector adapters 22 and the interconnectors 23 are not specifically limited herein.

It should be noted that in some embodiments the connecting device 20 may be designed without the use of the connecting base 21 and the fixing board 24. Instead, the optical connector adapters 22, the interconnectors 23, and the circuit board 25 are disposed on external devices.

Referring to FIGS. 5, 5A, and 5B in combination with FIG. 1, FIG. 5 is a schematic perspective exploded view of the optoelectronic processing device 3 in accordance with an embodiment of the present application, FIG. 5A is a schematic assembly view of an optoelectronic transceiver module 31 of the optoelectronic processing device 3, and FIG. 5B is a schematic exploded view of FIG. 5A. The optoelectronic processing device 3 further includes a load board 35 and a main board 36. The load board 35 is a printed circuited board disposed on the main board 36, and the main board 36 is fixed to the first lid portion 11 of the seal lid 10. In some embodiments, the co-packaged optics module 30 is disposed on the load board 35 and includes a first casing 301 arranged on the load board 35, a second casing 302 detachably assembled with the first casing 301, a plurality of the optoelectronic transceiver modules 31, and a processing unit 34.

As shown in FIG. 5, the optoelectronic transceiver modules 31 are electrically connected to the processing unit 34 that are sealed between the first casing 301 and the second casing 302. Specifically, each of the optoelectronic transceiver modules 31 includes an optoelectronic transceiver connector 32 and an optical fiber assembly 33 connected to the optoelectronic transceiver connector 32. In some embodiments, the processing unit 34 may include one or a plurality of electronic integrated circuits (EIC), such as microprocessors, application specific integrated circuits (ASIC), or memory, and one or a plurality of photonic integrated circuits (PIC).

Still referring to FIGS. 5, 5A, and 5B, in some embodiments, the optoelectronic transceiver module 31 includes a detachable optical coupling structure including a first connector (such as the optoelectronic transceiver connector 32) and a second connector (such as the optical fiber assembly 33). The second connector is detachably connected to the first connector that can achieve the effect of easy replacement of the optical fiber assembly 33. As shown in FIGS. 5A and 5B, the optoelectronic transceiver connector 32 includes a base 320 and a waveguide device 321. The base 320 includes a lower surface 320B, an upper surface 320T, and a front end 320F connected between the lower surface 320B and the upper surface 320T. In some embodiments, a cutout portion 322 is formed in the base 320 and is recessed from the front end 320F, and the waveguide device 321 is disposed in the cutout portion 322. In detail, the cutout portion 322 is configured to pass through parts of the lower surface 320B, the upper surface 320T, and the front end 320F of the base 320.

In some embodiments, as shown in FIG. 5B, a plurality of positioning elements 323 are symmetrically arranged on the front end 320F of the base 320 with respect to a middle of the base 320, and are spaced apart from each other on opposite sides of the cutout portion 322 and the waveguide device 321. A retaining wall 324 is formed on the base 320 and bends and extends downward from the lower surface 320B such that the base 320 has an inverted L-shaped cross-sectional profile. In this embodiment, there are two positioning elements 323, which are pin-like in shape and extend in an outward direction from the front end 320F on the retaining wall 324, respectively. In some embodiments, the base 320 is made of material having the characteristic of high temperature resistance, such as ceramic or metal, which is, for example, zirconium dioxide (ZrO₂). Alternatively, the base 320 may be made of non-metal material, such as organic binders (e.g., resin), polymer, or plastic.

Preferably, the waveguide device 321 is made of a material containing, for example, silica. Alternatively, the waveguide device 321 may be made of a material containing silicon-on-insulator (SOI), lithium niobate (LiNbO₃), or polymers. In some embodiments, the waveguide device 321 may be formed using a material of such as fused silica, quartz, glass, borosilicate glass, etc. It should be noted that the waveguide device 321 includes a planar lightwave circuit (PLC). In some embodiments, the planar lightwave circuit may be configured in various ways, including, but not limited to, a straight line circuit, a splitter circuit, an arrayed waveguide grating wavelength multiplexer, and a cross connect-type circuit. Different types of waveguide circuits or devices can be utilized for the planar lightwave circuit in the embodiments of the present application.

Still referring to FIGS. 5 to 5B, in some embodiments, the optical fiber assembly 33 includes the optical fibers 331 and a mating connector 332 structured to be detachably connected to the optoelectronic transceiver connector 32. The optical fibers 331 have a plurality of fiber ends 333 terminated at the mating connector 332 (as shown in FIG. 5A). In this embodiment, the mating connector 332 functions as an optical multi-channel connector and includes a connecting surface 334 arranged facing the front end 320F of the base 320, and a plurality of recesses (not show) of the mating connector 332 arranged to correspond to the pin-like positioning elements 323 (as shown in FIG. 5B). As shown in FIG. 5A, the optical fiber assembly 33 is plugged into the optoelectronic transceiver connector 32. As shown in FIG. 5B, the optical fiber assembly 33 can be removed from the base 320 of the optoelectronic transceiver connector 32.

In this arrangement, as shown in FIG. 5A, the fiber ends 333 of the optical fibers 331 are positioned to directly face the cutout portion 322 at the front end 320F of the base 320 to enable signal transmission between the optical fibers 331 and the waveguide device 321 in a way of surface coupling. It should be noted that the signal transmission between the optical fibers 331 and the waveguide device 321 is not limited to the surface coupling type as described above, and may be various in forms of optical coupling.

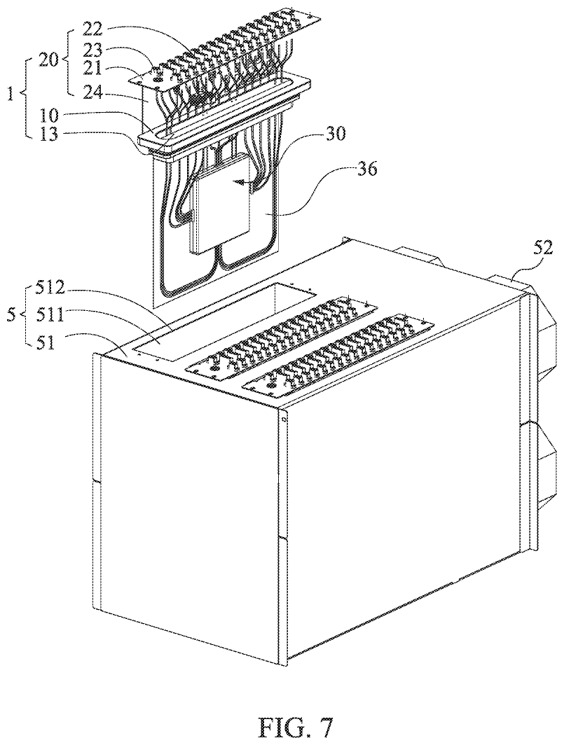

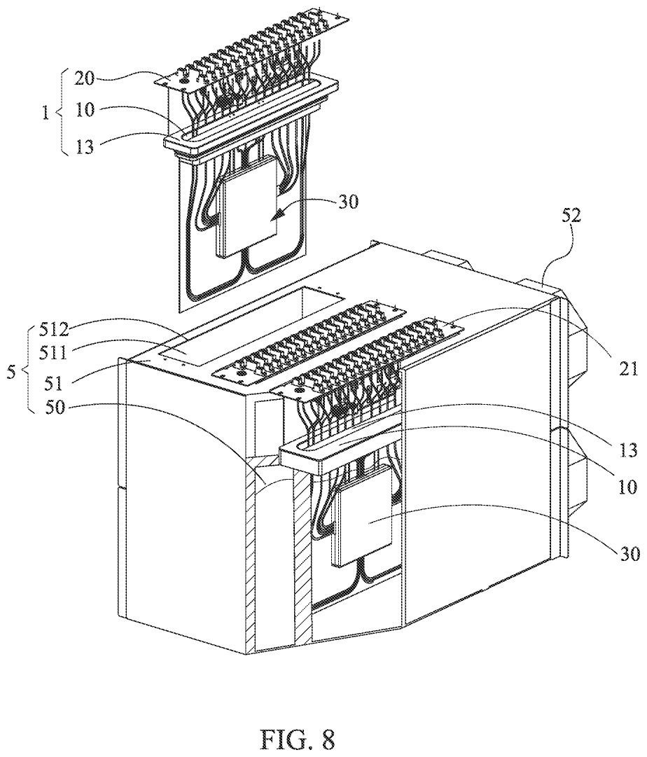

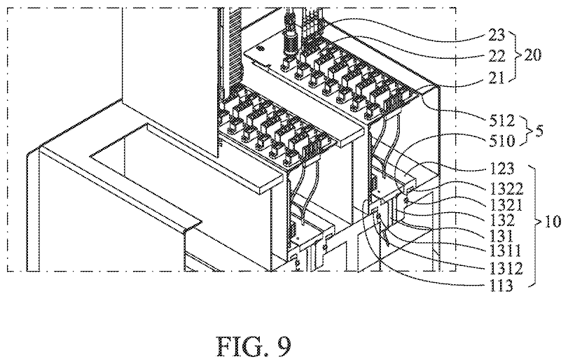

Referring to FIGS. 6 to 9, FIG. 6 is a schematic partial cross-sectional view of a tank body 51 of the immersion cooling apparatus 5 in accordance with an embodiment of the present application, FIG. 7 is a schematic perspective view showing the sealing structure 1 is pluggable into the tank body 51, FIG. 8 schematically shows a partial cross-sectional view of the tank body 51 of FIG. 7, and FIG. 9 is an enlarged cross-sectional view schematically showing the sealing structure 1 is plugged into the immersion cooling apparatus 5. As shown in FIGS. 6 and 7, the immersion cooling apparatus 5 includes the tank body 51, which is structured to have a plurality of cooling rooms 511. Each of the cooling rooms 511 is filled with a fluid coolant 50, such as cold water or a dielectric cooling liquid, for cooling the co-packaged optics module 30. In this embodiment, each of the cooling rooms 511 of the tank body 51 is shaped with the opening portion 510, which is sized and shaped to fit snugly around the sealing lid 10 (see FIG. 9). In addition, a top of the tank body 51 forms a plurality of entrance openings 512 located over and communicate with respective opening portions 510. Each of the entrance openings 512 is sized to support the respective connecting base 21 of the connecting device 20.

In some embodiments, as shown in FIGS. 6 and 7, the immersion cooling apparatus 5 further includes a circulation cooling assembly 52 arranged on a side of the tank body 51 to better the cooling performance.

Still referring to FIGS. 7 to 9, in use, the main board 36 along with the co-packaged optics module 30 is plugged into the cooling room 511 such that the co-packaged optics module 30 is immersed in the fluid coolant 50, the sealing lid 10 is in a snug fit with the opening portion 510 along with the first tab 112 and the second tab 122 positioned on the opening portion 510, and the connecting base 21 is supported on the entrance opening 512 of the tank body 51. Specifically, after the sealing lid 10 is fit in place, the first lower ring portion 1311 and the second lower ring portion 1321 are snug against peripheries of the opening portion 510, and the first upper ring portion 1312 and the second upper ring portion 1322 are snug against a top surface around the opening portion 510, so that the cooling room 511 is in an excellent hermetic state.

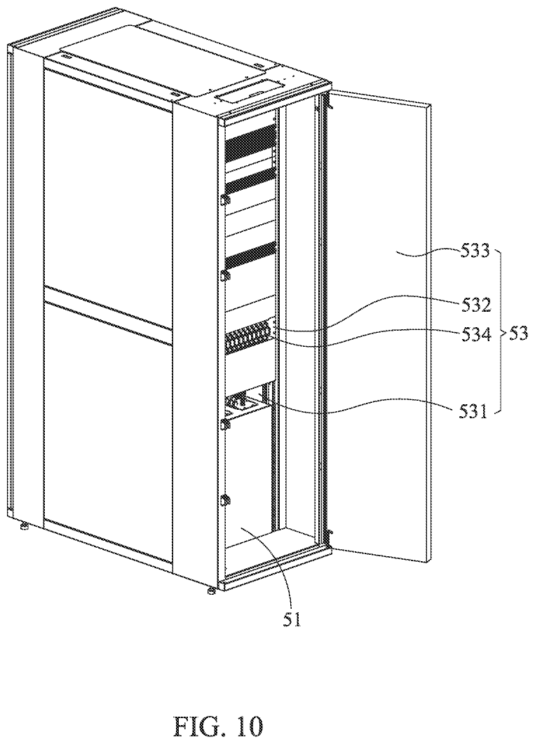

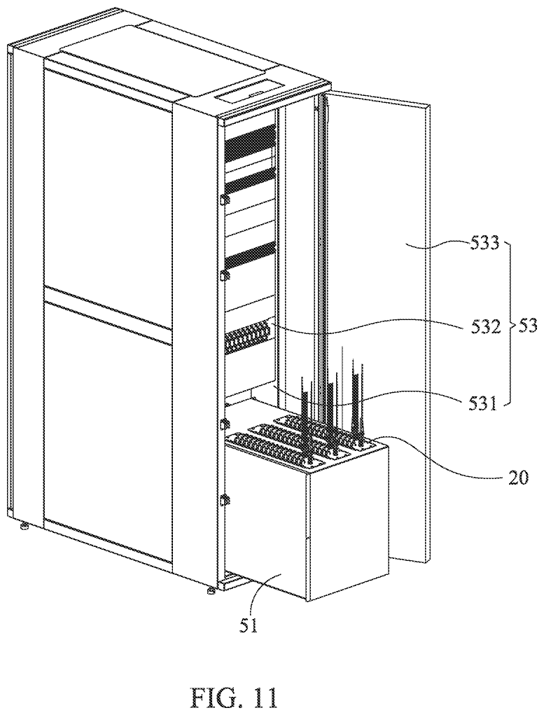

Referring to FIGS. 10 and 11, FIG. 10 is a schematic perspective view showing the tank body 51 with the sealing structure 1 is placed in a storage casing 53 in accordance with an embodiment of the present application, and FIG. 11 is a schematic perspective view showing the tank body 1 of FIG. 10 is drawn from the storage casing 53. As shown in FIG. 10, the immersion cooling apparatus 5 includes a storage casing 53 including a plurality of units of storage space 531, a rack 532, a cover 533 to close the storage space 531, and a plurality of terminal connectors 534 arranged on the rack 532. In some embodiments, the tank body 51 is placed in and drawable from the storage space 531, and the optical connector adapters 22 and the interconnectors 23 are electrically connected to the terminal connectors 534, respectively. The optoelectronic processing device 3 immersed in the tank body 51 can be electrically and optically connected to external devices through the terminal connectors 534 for realizing electrical and optical signal transmission.

Accordingly, the sealing structure provided in the embodiments of the present application renders the optoelectronic processing device in the tank body of the immersion cooling apparatus excellent hermetic, which prevents the fluid coolant leakage from the tank body, thus ensuring the co-packaged optics module is maintained in a desired temperature and enabling a good condition of the optoelectronic processing device. In addition, the detachable combination of the first lid portion and the second lid portion along with the first sealing part and the second sealing part obtains the advantage of easy replacement of the optical fiber assembly, thereby solving the problem of difficulty in replacing the signal transmission lines.

While the application has been disclosed in conjunction with a description of certain embodiments, including those that are currently believed to be the preferred embodiments, the detailed description is intended to be illustrative and should not be understood to limit the scope of the present application. As would be understood by one of ordinary skill in the art, embodiments other than those described in detail herein are encompassed by the present application. Modifications and variations of the described embodiments may be made without departing from the scope of the application.

What is claimed is:

1. A sealing structure for an immersion cooling apparatus, the immersion cooling apparatus housing and cooling an optoelectronic processing device comprising a processing unit and a plurality of optical fibers connected to the processing unit, and the sealing structure comprising:
a first lid portion;
a second lid portion detachably connected to the first lid portion; and
a sealing component comprising a first sealing part and a second sealing part, wherein the first sealing part is disposed on the first lid portion and comprising a first sealing surface, the second sealing part is disposed on the second lid portion and comprising a second sealing surface, and the first lid portion, the second lid portion, and the sealing component is jointly defining a sealing lid hermetically covering an opening portion of a tank body included in the immersion cooling apparatus; and
wherein the first sealing surface and the second sealing surface are in contact with each other, and part of each of the optical fibers is sandwiched between and encompassed by the first sealing surface and the second sealing surface.

2. The sealing structure for the immersion cooling apparatus of claim 1, wherein the first sealing part comprises a first inner surface provided opposite to the first sealing surface and attached to the first lid portion, and a first lower ring portion extending from the first inner surface toward the first lid portion and tightened against the first lid portion.

3. The sealing structure for the immersion cooling apparatus of claim 2, wherein the first sealing part further comprises a first upper ring portion arranged on the first inner surface and located above and extending beyond the first lower ring portion.

4. The sealing structure for the immersion cooling apparatus of claim 1, wherein the second sealing part comprises a second inner surface provided opposite to the second sealing surface and attached to the second lid portion, and a second lower ring portion extending from the second inner surface toward the second lid portion and tightened against the second lid portion.

5. The sealing structure for the immersion cooling apparatus of claim 4, wherein the second sealing part further comprises a second upper ring portion arranged on the second inner surface and located above and extending beyond the second lower ring portion.

6. The sealing structure for the immersion cooling apparatus of claim 1, wherein the first lid portion comprises a first recessed portion arranged on a side of the first lid portion, and the second lid portion comprises a second recessed portion arranged on a side of the second lid portion and facing the first recessed portion, wherein a part of the first sealing part is positioned in the first recessed portion, and a part of the second sealing part is positioned in the second recessed portion.

7. The sealing structure for the immersion cooling apparatus of claim 1, wherein the first lid portion comprises a first tab protruding outward from peripheries of the first lid portion, the second lid portion comprises a second tab protruding outward from peripheries of the second lid portion, and the first tab and the second tab are positioned on the opening portion of the immersion cooling apparatus.

8. The sealing structure for the immersion cooling apparatus of claim 1, wherein the first lid portion comprises a plurality of fastening elements positioned on opposite ends of the first lid portion, and the second lid portion comprises a plurality of fixing portions positioned on opposite ends of the second lid portion and structured to connect to the fastening elements, respectively.

9. The sealing structure for the immersion cooling apparatus of claim 1, further comprising a connecting device positioned on an entrance opening formed in the tank body, wherein the connecting device comprises a connecting base on which a plurality of optical connector adapters and a plurality of interconnectors are arranged.

10. The sealing structure for the immersion cooling apparatus of claim 9, wherein the connecting device further comprises a fixing board connected between the connecting base and the sealing lid, and a circuit board mounted on the fixing board.

11. The sealing structure for the immersion cooling apparatus claim 10, wherein the immersion cooling apparatus comprises a storage casing comprising a rack, and a plurality of terminal connectors arranged on the rack and defining a storage space, wherein the tank body is placed in and drawable from the storage space, and the optical connector adapters and the interconnectors are electrically connected to the terminal connectors respectively.

12. The sealing structure for the immersion cooling apparatus claim 1, wherein the optoelectronic processing device further comprises a main board, a load board disposed on the main board, and a co-packaged optics module disposed on the load board, wherein the co-packaged optics module comprises a first casing arranged on the load board, a second casing assembled with the first casing, and an optoelectronic transceiver module, and the optoelectronic transceiver module and the processing unit are sealed between the first casing and the second casing.

13. The sealing structure for the immersion cooling apparatus of claim 12, wherein the optoelectronic transceiver module comprises a detachable optical coupling structure comprises a first connector and a second connector detachably connected to the first connector.

14. The sealing structure for the immersion cooling apparatus of claim 12, wherein the optoelectronic processing device further comprises a plurality of functional lines, a part of each of the functional lines extends into the co-packaged optics module, and another part of each of the functional lines passes through the first sealing part or is sandwiched between and encompassed by the first sealing surface and the second sealing surface.

15. A sealing structure for an immersion cooling apparatus, wherein the immersion cooling apparatus is for housing and cooling an optoelectronic processing device, and the sealing structure comprises:
a first lid portion
a second lid portion detachably connected to the first lid portion; and
a sealing component disposed on the first lid portion and the second lid portion, wherein the optoelectronic processing device comprises a load board, a first casing arranged on the load board, a second casing assembled with the first casing, and an optoelectronic transceiver module sealed between the first casing and the second, and wherein the optoelectronic transceiver module comprises a detachable optical coupling structure, and the optical coupling structure comprises:
a first connector disposed on the load board and comprising:
a base; and
a waveguide device disposed in the base; and
a second connector comprising a plurality of optical fibers,
wherein the second connector is detachably connected to the first connector.

16. The sealing structure for the immersion cooling apparatus of claim 15, wherein the sealing component comprises a first sealing part and a second sealing part, the first sealing part is disposed on the first lid portion and comprises a first sealing surface, the second sealing part is disposed on the second lid portion and comprises a second sealing surface, and the first lid portion, the second lid portion, and the sealing component jointly defining a sealing lid hermetically covering an opening portion included in the immersion cooling apparatus; and
wherein the first sealing surface and the second sealing surface are in contact with each other, and part of each of the optical fibers are sandwiched between and encompassed by the first sealing surface and the second sealing surface.
